(19) United States
(12) Patent Application Publication
(10) Pub. No.: US 2006/0049886 A1
(43) Pub. Date: Mar. 9, 2006

(54) On-die record-of-age circuit

(76) Inventors: Victor M. Agostinelli JR., Portland, OR (US); Ben J. Eapen, Portland, OR (US); Paul F. Newman, Hillsboro, OR (US); Glenn Shirley, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/936,767

(22) Filed: Sep. 8, 2004

(51) Int. Cl. H03L 1/00

(52) U.S. Cl. 331/175

(57) ABSTRACT

An on-die record-of-age circuit includes a reference oscillator circuit, an aging oscillator circuit, and a frequency comparator. A circuit component is coupled to receive a logic clock signal and to execute a function during operation. The reference oscillator circuit generates a reference clock signal having a reference frequency. The aging oscillator circuit generates an aging clock signal having an aging frequency that degrades during operation of the circuit component. The frequency comparator is coupled to compare the aging frequency with the reference frequency to generate an age signal, which depends on the operational age of the circuit component.

### TECHNICAL FIELD

This disclosure relates generally to semiconductor devices, and in particular but not exclusively, relates to determining the age of a semiconductor device.

### BACKGROUND INFORMATION

As semiconductor dies age, the reliability of internal components begins to diminish. The semiconductor die ages during operational use during which the internal components are exposed to varying operational temperatures and voltages. In fact, the effects of aging are proportional to the cumulative temperatures and voltages experienced during use. Thus, internal components that operate at higher temperatures and voltages age faster and deteriorate quicker than those components experiencing more moderate temperatures and voltages.

One such aging effect is Hot Carrier Degradation. Hot Carrier Degradation results when charge carriers become trapped within the gate oxide of a transistor. The trapped charge carriers accumulate over time, creating a built-in charge within the gate oxide of the transistor. This trapped charge decreases the carrier mobility across the channel of the transistor and alters the transistor threshold voltage V_{TH}. Hot Carrier Degradation is aggravated by elevated operating temperatures and voltage, and has a cumulative effect proportional to age. Negative-type metal oxide semiconductor (“NMOS”) components are particularly susceptible to Hot Carrier Degradation.

Another such aging effect is Negative Bias Temperature Instability (“NBTI”). The NBTI mechanism is an electrochemical reaction that involves the electric field, holes, silicon-hydrogen bonds, and temperature. During operation, DC bias voltages generate interface traps between the gate oxide and silicon substrate of a transistor. These interface traps accumulate over time and have the effect of shifting the threshold voltage V_{TH} and reducing drive current. Positive-type metal oxide semiconductor (“PMOS”) devices particularly suffer from the NBTI effect.

Accordingly, different internal components of an integrated circuit have varying reliable lifetimes. These reliable lifetimes are dependent upon localized environments subjected to localized operational voltages and temperatures and upon the specific stress history of the circuit component. Components residing in high-use, high-stress environments will have shorter reliable lifetimes.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating an on-die record-of-age circuit, in accordance with an embodiment of the present invention.

FIG. 2 is a graph illustrating how an aging oscillator circuit generates an aging clock signal having an aging frequency that degrades with time, in accordance with an embodiment of the present invention.

FIG. 3 is a flow chart illustrating a process for logging and/or tracking operational age of a circuit component, in accordance with an embodiment of the present invention.

FIG. 4 is a flow chart illustrating a process for throttling a clock signal of a circuit component as the circuit component exceeds its reliable lifetime for a given clock frequency, in accordance with an embodiment of the present invention.

FIG. 5 is a block diagram illustrating a processor having multiple on-die record-of-age circuits to track operational age of multiple circuit components, in accordance with an embodiment of the present invention.

FIG. 6 is a circuit diagram illustrating a reference oscillator circuit for generating a reference clock signal having a reference frequency, in accordance with an embodiment of the present invention.

FIG. 7 is a circuit diagram illustrating an aging oscillator circuit for generating an aging clock signal having an aging frequency that degrades over time, in accordance with an embodiment of the present invention.

FIG. 8 illustrates a demonstrative system for implementing embodiments of the present invention.

### DETAILED DESCRIPTION

Embodiments of a system and method for providing an on-die record-of-age of semiconductor circuit components are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

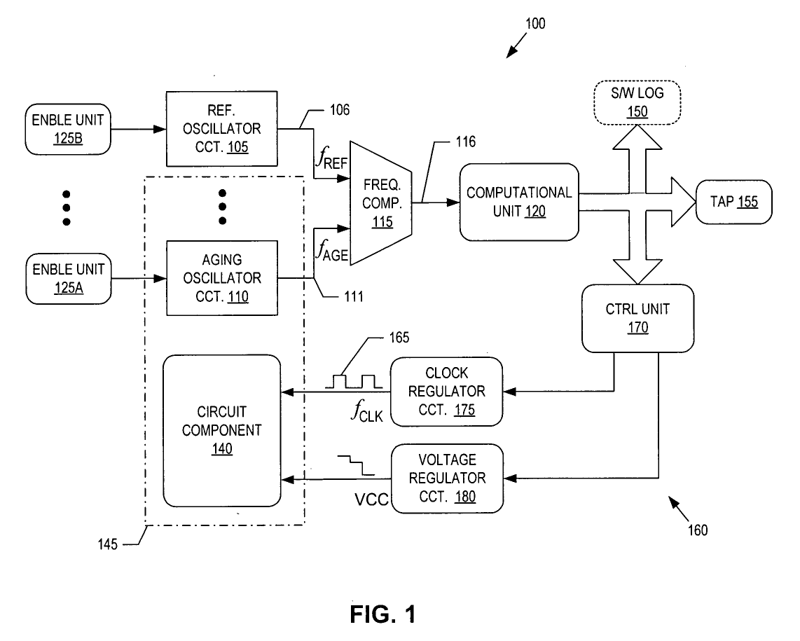

FIG. 1 is a block diagram illustrating an on-die record-of-age circuit 100, in accordance with an embodiment of the present invention. The illustrated embodiment of record-of-age circuit 100 includes a reference oscillator circuit 105, one or more aging oscillator circuits 110, a frequency comparator 115, a computational unit 120, and enable units 125A and 125B.

In one embodiment, aging oscillator circuit 110 includes a ring oscillator that generates an aging clock signal 111 having an aging frequency f_{AGE} that degrades during operation of aging oscillator circuit 110. Enable unit 125A is coupled to selectively enable or disable aging oscillator circuit 110. In one embodiment, enable unit 125A enables aging oscillator circuit 110 only when a circuit component 140 is operating. Aging oscillator circuit 110 is positioned proximate/adjacent to circuit component 140 (as illustrated with box 145) such that aging oscillator circuit 110 and circuit component 140 experience similar localized operational stresses (e.g., temperature, voltage, etc.). Since aging oscillator circuit 110 and circuit component 140 are exposed to a similar operating environment, both aging oscillator circuit 110 and circuit component 140 age at approximately the same rate. Accordingly, aging oscillator circuit 110 tracks the operational age of circuit component 140.

In one embodiment, reference oscillator circuit 105 includes a ring oscillator that generates a reference clock signal 106 having a reference frequency f_{REF}. Enable unit 125B is coupled to selectively enable or disable reference oscillator circuit 105. In one embodiment, reference oscillator circuit 105 is enabled for short periods of time, just long enough to compare f_{REF} of reference clock signal 106 with f_{AGE} of aging clock signal 111. When reference oscillator circuit 105 is disabled, reference oscillator circuit 105 is electrically isolated from circuit component 140 and does not experience the aging effects stimulated by applied voltage. In one embodiment, reference oscillator circuit 105 may also be thermally isolated from circuit component 140 when disabled by enable unit 125B. Relative to the cumulative operating time of circuit component 140 and aging oscillator circuit 110, reference oscillator circuit 105 is operated for a very short period of time.

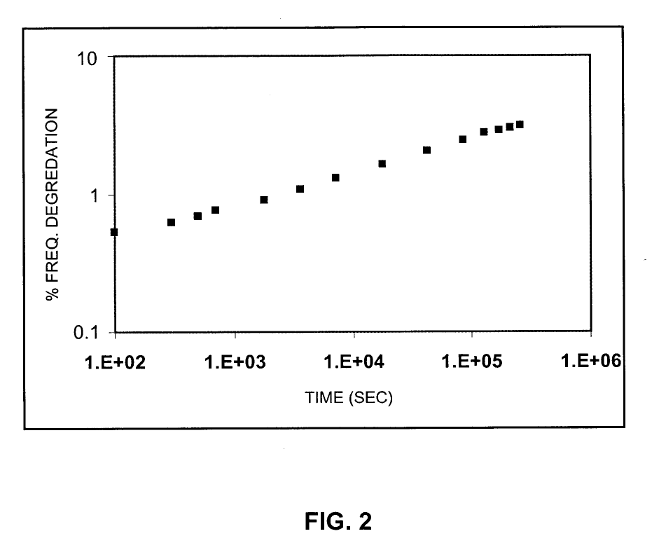

During operational use, semiconductor devices (e.g., aging oscillator circuit 110, circuit component 140, and the like) are subjected to operational factors, such as temperature and voltage. These operational factors stimulate cumulative aging effects, such as Hot Carrier Degradation, Negative Bias Temperature Instability (“NBTI”), and the like. These aging effects cause the semiconductor device to degrade in a statistically predictable manner that is proportional to operational time. FIG. 2 is a demonstrative graph illustrating how f_{AGE} degrades versus time. Accordingly, comparing f_{AGE} of aging clock signal 111, which is controlled by enable unit 125A to age at the same rate as circuit component 140, with f_{REF} of reference clock signal 106, which is controlled by enable unit 125B to age a negligible amount, provides a sort of odometer reading tracking the operational age of circuit component 140. In other words, the difference f_{REF}−f_{AGE} is proportional to the operational age of circuit component 140.

In one embodiment, frequency comparator 115 is coupled to receive and compare reference clock signal 115 and aging clock signal 111. In response, frequency comparator 115 generates an age signal 116 that is proportional to the operational age of circuit component 140. Age signal 116 generated by frequency comparator 115 may then be input into computational unit 120 for processing.

In one embodiment, computational unit 120 may be a processing engine, such as a processor core, or even a software engine executed by a processor. Computational unit 120 may execute one or more of a number of functions on age signal 116. In one embodiment, computational unit 120 generates a software log 150 to store periodic odometer readings indicating the operational age of circuit component 140. The software log 150 may be generated by computational unit 120 with reference to a lookup table indexing values of age signal 116 to age values (e.g., operational time measured in years, days, hours or the like). The approximated ages for each index value of age signal 116 may be computed and stored to the lookup table using known models of how semiconductors devices age. Alternatively, the approximated ages may be determined by subjecting a test chip to operational conditions for a period of time, measuring the frequency degradation, and extrapolating the frequency degradation over longer periods of time. Other techniques for computing the operational age of circuit component 140 based on age signal 116 may be implemented within the spirit of the present invention.

Computational unit 120 may output age values to a test access port (“TAP”) 155. TAP 155 may be accessible by a technician wishing to obtain diagnostic measurements and data. It should be appreciated that computational unit 120 may be by-passed altogether and age signal 116 directly coupled to TAP 155 for direct output.

The components of record-of-age circuit 100 may be coupled into a feedback loop 160 to control a clock frequency f_{CLK} of a logic clock signal 165 timing circuit component 140 and/or to control a supply voltage VCC powering circuit component 140. Computational unit 120 may provide age readings to a control unit 170. In one embodiment, control unit 170 is coupled to a clock regulator circuit 175 to control f_{CLK} of logic clock signal 165, based at least in part on the age value being representative of the operational age of circuit component 140. In one embodiment, control unit 170 is coupled to a voltage regulator circuit 180 to control the supply voltage VCC, based at least in part on the age value being representative of the operational age of circuit component 140. It should be appreciated that computational unit 120 could be bypassed and age signal 116 coupled directly to control unit 170.

The processes explained below are described in terms of computer software and hardware. The techniques described may constitute machine-executable instructions embodied within a machine (e.g., computer) readable medium, that when executed by a machine will cause the machine to perform the operations described. Additionally, the processes may be embodied within hardware, such as an application specific integrated circuit (“ASIC”) or the like. The order in which some or all of the process blocks appear in each process should not be deemed limiting. Rather, one of ordinary skill in the art having the benefit of the present disclosure will understand that some of the process blocks may be executed in a variety of orders not illustrated.

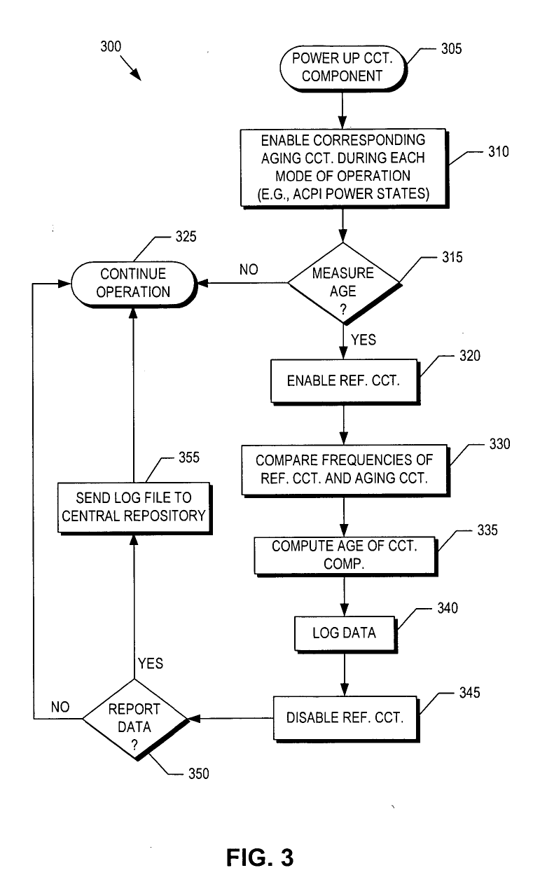

FIG. 3 is a flow chart illustrating a process 300 for logging and/or tracking the operational age of circuit component 140, in accordance with an embodiment of the present invention. In a process block 305, circuit component 140 is powered up. In one embodiment, circuit component 140 may be a subcomponent of a larger integrated circuit (“IC”) disposed on a semiconductor die. In this case, circuit component 140 may power up when power is applied to the semiconductor die. Alternatively, the larger IC could already be turned on and prior to process block 305, circuit component 140 is idle or in a low power state.

In a process block 310, enable unit 125A enables aging oscillator circuit 110. Enable unit 125A is coupled to enable aging oscillator circuit 110 either simultaneously with powering up circuit component 140 or shortly thereafter. In one embodiment, enable unit 125A may simply be a short circuit to a VCC power path.

In one embodiment, circuit component 140 may have multiple operating modes. Each operating mode may correspond to a different power mode, frequency mode, temperature mode, or the like, of circuit component 140. In this embodiment, multiple aging oscillator circuits 110 may be disposed proximate/adjacent to circuit component 140, each aging oscillator circuit 110 corresponding to a possible operating mode during which circuit component 140 may execute. Accordingly, enable unit 125A would enable the corresponding aging oscillator circuit 110 dependent upon the current operating mode of circuit component 140 and disable all others. Doing so allows each oscillator circuit 110 to track how long circuit component 140 has existed in each of the multiple operating modes.

For example, an Advance Configuration and Power Interface (“ACPI”) Specification (e.g., ACPI Specification, Revision 2.0a, Mar. 31, 2002) defines multiple power management states—global states Gx, system sleeping states Sx, CPU power states Cx, device states Dx. If circuit component 140 is a subcomponent of a processor, then circuit component 140 may operate in any one of the representative CPU power states illustrated in Table 1.

TABLE 1

| State | Description |
|---|---|
| C0 | Processor executes instruction, no |
| | power is saved |
| C1 | Processor is halted |
| C2 | Lower power, higher latency state |
| C3 | Further power-down state with |
| | higher resume latency |

In this example, four aging oscillator circuits 110 could be disposed proximate to circuit component 140 corresponding to each CPU power state C0, C1, C2, and C3. Enable unit 125A could selectively enable the corresponding aging oscillator circuit 110 depending upon the current CPU power state of the processor.

In a decision block 315, if an age measurement of circuit component 140 is desired, process 300 continues to a process block 320. Otherwise, process 300 continues to a process block 325 to continue regular operation.

In process block 320, enable unit 125B enables reference oscillator circuit 105. Once reference oscillator circuit 105 is enabled and reference clock signal 106 is allowed to stabilize, frequency comparator 115 compares f_{AGE} of aging clock signal 111 with f_{REF} of reference clock signal 106 to generate age signal 116. In one embodiment, age signal 116 is a voltage level equal to A·(f_{REF}−f_{AGE}), where A is a constant scaling factor. In this embodiment, the voltage level depends on an operational age of circuit component 140.

In a process block 335, computational unit 120 receives aging signal 116 and computes an operational age for circuit component 140. As discussed above, the operational age may be generated with reference to a lookup table, by executing an algorithm, or the like.

In a process block 340, computational unit 120 logs the aging data (e.g., operational age, aging signal 116, etc.) into software log 150. Once the operational age of circuit component 140 has been determined, enable unit 125B disables reference oscillator circuit 105 to prevent reference oscillator circuit 105 from degrading with time. In one embodiment, disabling reference oscillator circuit 105 includes electrically isolating reference oscillator circuit 105 from circuit component 140.

In an embodiment having multiple aging oscillator circuits 110 to track multiple operating modes of circuit component 140, process blocks 330, 335, 340, and 345 may be repeated for each aging oscillator circuit 110. The aging signals 116 generated would each depends on the time of circuit component 140 spent in each operating mode. A cumulative operating age including all operating modes may also be tallied by computational unit 120.

The aging data stored within software log 150 may be accumulated over a period of time and saved for reporting back to a central repository. If the aging data is to be reported back to the central repository (decision block 350), then process 300 continues to a process block 355. In process block 355 software log 150, or portions thereof, are transmitted over a network (e.g., LAN, WAN, Internet, etc.) to the central repository. This central repository could then be accessed, parsed, and analyzed to determine how often circuit component 140 is used and in what operating mode. For example, an Original Equipment Manufacture (“OEM”) may collect the aging data to help develop more accurate usage models. Based on the usage models, the OEM may choose to fortify certain high-use, extreme environment locations within an IC.

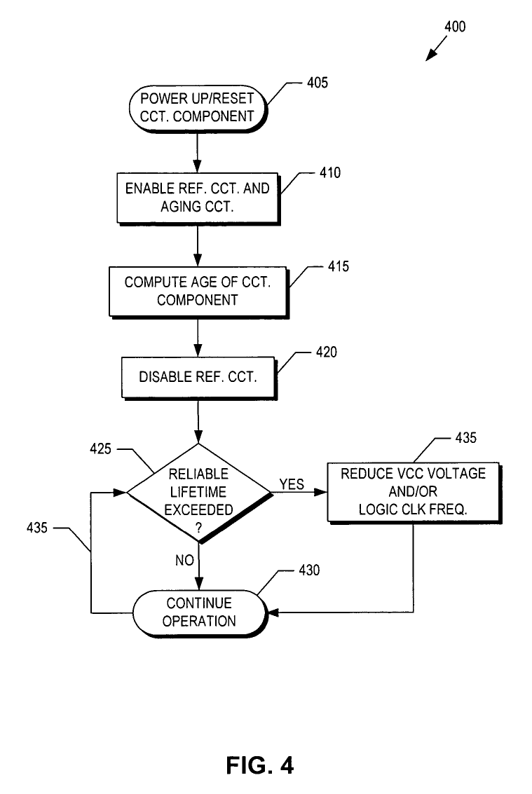

FIG. 4 is a flow chart illustrating a process 400 for throttling logic clock signal 165 used to clock circuit component 140 and/or adjust the supply voltage VCC powering circuit component 140, in accordance with an embodiment of the present invention.

In a process block 405, circuit component 140 is powered up. In a process block 410, aging oscillator circuit 110 and reference oscillator circuit 105 are enabled by enable units 125A and 125B, respectively. In a process block 415, the operational age of circuit component 140 is computed, as described above. In a process block 420, reference oscillator circuit 105 is disabled after the operational age has been computed to prevent reference oscillator circuit 105 from degrading.

In a decision block 425, if a reliable lifetime of circuit component 140 has not been exceeded, then process 400 continues to a process block 430 and circuit component 140 continues regular operation. However, if control unit 170 determines that the reliable lifetime of circuit component 140 has been exceeded, then process 400 continues to a process block 435. In process block 435, control unit 170 selectively directs clock regulator circuit 175 to decrease f_{CLK} of logic clock signal 165 and/or directs voltage regulator circuit 180 to adjust the supply voltage VCC.

Reducing f_{CLK}, can effectively extend the operational lifetime of circuit component 140. More specifically, as circuit component 140 ages and the cumulative effects of Hot Carrier Degradation, NBTI, and the like become more pronounced and significant, circuit component 140 may fail at higher frequencies while still remaining functional at lower frequencies, notwithstanding increased latency.

Similarly, adjusting the supply voltage VCC can extend the reliable lifetime of circuit component 140. As discussed above, aging occurs at a greater rate for higher DC operating voltages. Accordingly, as the reliable lifetime of circuit component 140 approaches, the supply voltage VCC may be incrementally decreased to reduce the rate of subsequent aging and thereby extend the functional life of circuit component 140. Alternatively, once circuit component 140 does fail or is close to failure due to aging effects, increasing the supply voltage may extract additional short term operational time from circuit component 140, albeit at the expense of accelerating the aging process.

It should be appreciated that circuit component 140 may have a different reliable lifetime rated for each frequency step of logic clock signal 165. In other words, once f_{CLK} is decreased once in process block 435, process 400 may loop back to decision block 425 along process path 435 many times. Each time f_{CLK} of logic clock signal 165 is decreased, the reliable lifetime of circuit component 140 is incrementally increased. However, it should be appreciated that eventually decreasing f_{CLK} or adjusting the supply voltage VCC will no longer extend the reliable lifetime of circuit component 140, at which point catastrophic failure due to old age is unavoidable.

In some cases, a circuit may partially recover from Hot Carrier Degradation, NBTI, or the like during rest periods when the circuit is powered down. Accordingly, in one embodiment process 400 is executed each time circuit component 140 (or a system incorporating circuit component 140) cycles through a power-up sequence to recalculate the cumulative aging effects and account for partial rejuvenation during rest periods.

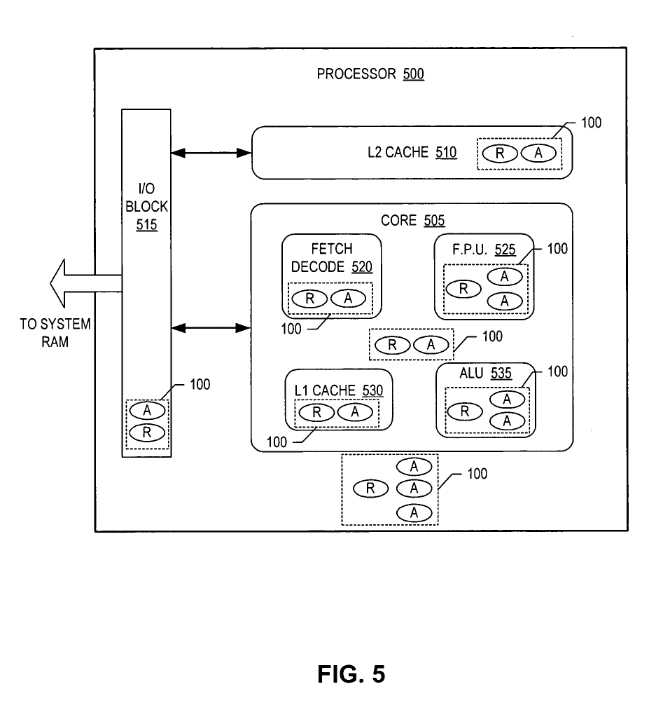

FIG. 5 is a block diagram illustrating a processor 500 including multiple on-die record-of-age circuits 100 to track operational ages of multiple circuit components, in accordance with an embodiment of the present invention. The illustrated embodiment of processor 500 includes a core 505, level-2 (“L2”) cache 510, and an input/output (“I/O”) block 515. The illustrated embodiment of core 505 includes a fetch decode unit 520, a floating-point math unit (“FPU”) 525, L1 cache 530, and an arithmetic logic unit (“ALU”) 535. It should be appreciated that one or more elements of processor 500 and core 505 have been excluded from FIG. 5 for the sake of clarity.

As illustrated, processor 500 may include several instances of record-of-age circuits 100 strategically disposed across the die of processor 500. Record-of-age circuits 100 may include only one reference oscillator circuit 105 (labeled as an “R”) and one aging oscillator circuit 110 (labeled as an “A”), such as the one included within fetch decode unit 520. Alternatively, record-of-age circuits 100 may include one reference oscillator circuit 105, but multiple aging oscillator circuits 110 to track multiple operating modes of the subcomponent (e.g., FPU 525 and ALU 535). Finally, although not illustrated, a single reference oscillator circuit 105 may be shared between multiple (or even all) record-of-age circuits 100 to conserve die real estate.

Although record-of-age circuits 100 are illustrated as internal to each subcomponent of processor 500, it should be appreciated that record-of-age circuits 100 may simply be disposed adjacent to or in close proximity to the corresponding subcomponent for which the particular record-of-age circuit 100 is tracking. Record-of-age circuits 100 may be disposed in strategic “hot zones” of processor 500 that generate high temperatures (e.g., FPU 525, ALU 535, etc.) or dispersed evenly (or randomly) across the die of processor 500 to accumulate general die aging data. Accordingly, embodiments of the present invention facilitate an aging record capable of tracking the operational age of an entire die in general, tracking the operational age of particular subcomponents, and even capable of tracking time spent by subcomponents within individual operating modes. This aging data may be logged over a defined period of time and periodically transmitted over a network to a central repository for use by OEMs and the like. This aging data may also be used to throttle global or local clocks (e.g., logic clock signal 165) and adjust global or local supply voltages (e.g., supply voltage VCC).

If an IC, such as processor 500, is enabled to detect circuit components that are subject to high-stress, and therefore rapid aging, in the user environment, circuit designers can make the affected circuit components more robust, thereby extending the functional lifetime of the entire IC. Alternatively, if the aging of circuit components can be detected by automatic mechanisms (such as record-of-age circuits 100) while in the user environment, then ICs may be developed with the built-in ability to adapt operating modes to reduce the likelihood of failure, and thereby extend the functional lifetime of the entire IC.

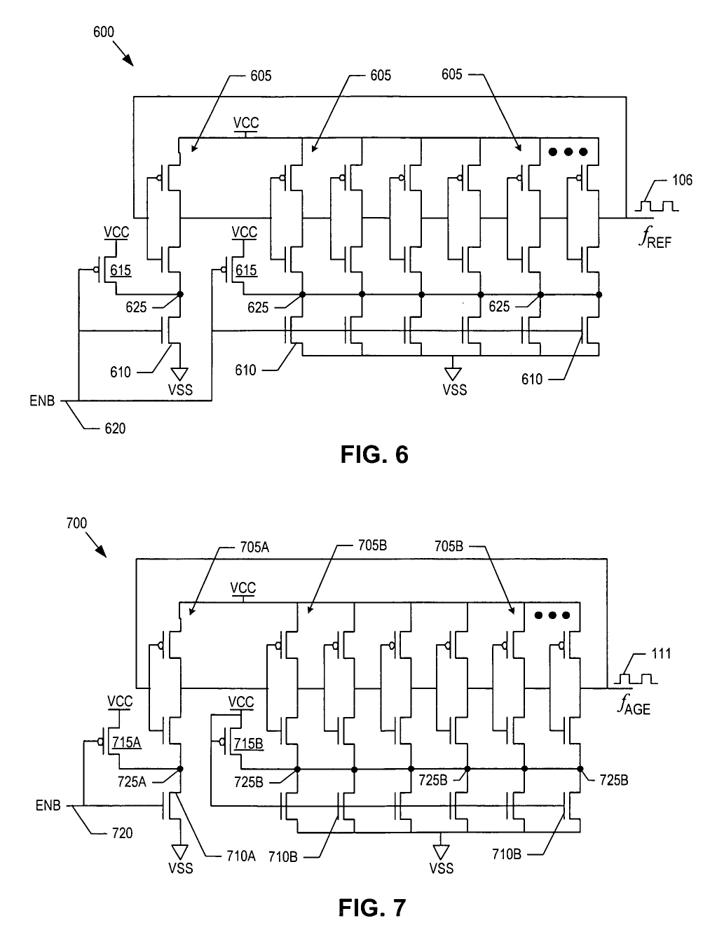

FIG. 6 is a circuit diagram illustrating a reference oscillator circuit 600, in accordance with an embodiment of the present invention. Reference oscillator circuit 600 is one possible embodiment of reference oscillator circuit 105.

The illustrated embodiment of reference oscillator circuit 600 includes inverter circuits 605, enable transistors 610, enable transistors 615, and an enable input 620. An odd number of inverter circuits 605 are cascaded with a last one of inverter circuits 605 having an output coupled to an input of a first one of inverter circuits 605. Inverter circuits 605 are coupled in a feedback loop to oscillate reference clock signal 106 having reference frequency f_{REF}. The reference frequency f_{REF} is dependent, in part, on the number of inverter circuits 605 cascaded in series. In one embodiment, 32 inverter circuits 605 are cascaded in series, though other embodiments may include more or less.

Enable transistors 610 each have a drain and source coupled in series between a corresponding one of inverter circuits 605 and a VSS power path. The gates of enable transistors 610 are coupled to enable input 620 to be selectively turned on and off. Enable input 620 is coupled to enable unit 125B and controllable thereby. Enable transistors 615 have drains and sources coupled in series between a VCC power path and nodes 625. Nodes 625 are located between enable transistors 610 and inverter circuits 605. Enable transistors 615 are coupled to nodes 625 to selectively short nodes 625 to the VCC power path in response to enable input 620. Shorting nodes 625 disables invert circuits 605 by raising both sides of the inverter circuits to the VCC supply voltage, thereby removing stress on the positive-type metal oxide semiconductor (“PMOS”) transistors in inverter circuits 605. Simultaneously with shorting nodes 625 to the VCC supply voltage, enable transistors 610 open circuit nodes 625 from the VSS ground voltage. Since transistors 610 are shorted at their drains and their combined parallel resistance is much smaller than the resistance of the transistors of inverter circuits 605, the reference frequency f_{REF} will remain substantially unaffected, even if transistors 610 degrade with time. In one embodiment, gate lengths of transistors 610 are increased to reduce the impact of hot carrier degradation.

FIG. 7 is a circuit diagram illustrating an aging oscillator circuit 700, in accordance with an embodiment of the present invention. Aging oscillator circuit 700 is one possible embodiment of aging oscillator circuit 110.

The illustrated embodiment of aging oscillator circuit 700 includes inverter circuits 705A and 705B (collectively 705), enable transistors 710A and 710B (collectively 710), enable transistors 715A and 715B (collectively 715), and an enable input 720. An odd number of inverter circuits 705 are cascaded with a last one of inverter circuits 705 having an output coupled to an input of a first one of inverter circuits 705. Inverter circuits 705 are coupled in a feedback loop to oscillate aging clock signal 111 having aging frequency f_{AGE}. The aging frequency f_{AGE} is dependent, in part, on the number of inverter circuits 705 cascaded in series, as well as the operational age of inverter circuits 705. In one embodiment, 32 inverter circuits 705 are cascaded in series, though other embodiments may include more or less.

Enable transistors 710 each have a drain and source coupled in series between a corresponding one of inverter circuits 705 and a VSS power path. The gates of enable transistors 710B are all coupled to a VCC power path to maintain enable transistors 710B in a permanent ON/conducting state. Enable transistors 715 have drains and sources coupled in series between the VCC power path and nodes 725. Nodes 725 are located between enable transistors 710 and inverter circuits 705. Enable transistor 715A has a gate coupled to enable input 720 to selectively enable/disable aging oscillator circuit 700. Enable input 720 is coupled to enable unit 125A and controllable thereby. Enable transistor 715A is coupled to node 725A to selectively short node 725A to the VCC power path in response to enable input 720. Shorting node 725A disables invert circuit 705A by raising both sides of inverter circuit 705A to the VCC supply voltage. Simultaneously with shorting node 725A to the VCC supply voltage, enable transistor 710A open circuits node 725A from the VSS ground voltage. Once inverter circuit 705A is disabled, aging oscillator circuit 700 will no longer oscillate. Similarly as discussed above, because transistors 710 are shorted at their drains and their combined parallel resistance is much smaller than the resistance of the transistors of inverter circuits 705, degradation of transistors 710 will not substantially affect aging frequency f_{AGE} generated by inverter circuits 705. In one embodiment, gate lengths of transistors 710 are also increased so as to reduce hot carrier aging effects thereon. It should be appreciated that embodiments of reference oscillator circuit 600 may also implement aging oscillator circuit 110, if it is left enabled during operation of a corresponding circuit component.

In one embodiment, the negative-type metal oxide semiconductor (“NMOS”) transistors and PMOS transistors that form inverter circuits 605 and 705 are oversized to smooth out process variations and defects introduced during fabrication. For example, the channel lengths of these NMOS and PMOS transistors may be increased by 50% over the minimum channel length for a particular fabrication technology and the gate widths may be increased by a factor of 10× over the minimum width for the particular fabrication technology.

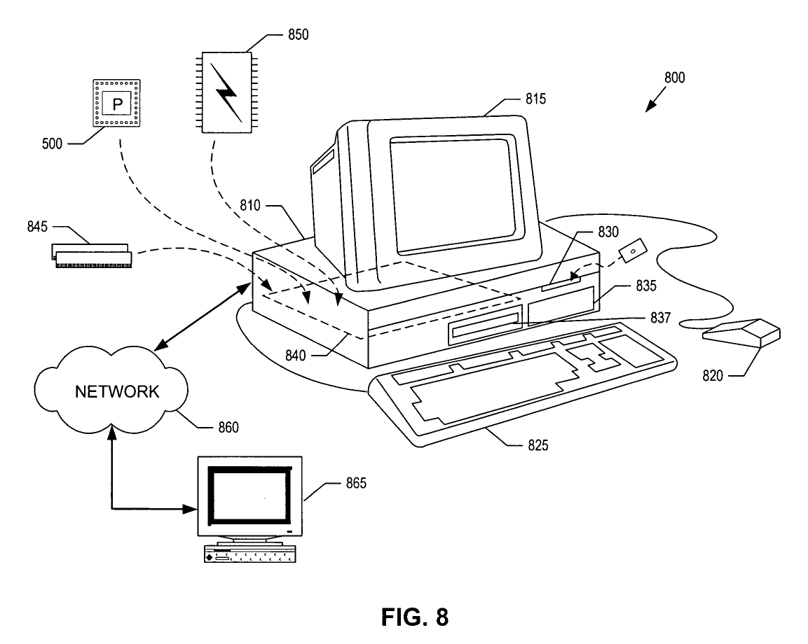

FIG. 8 is a diagram of a system 800 that may incorporate one or more record-of-age circuits 100, in accordance with embodiments of the present invention. The illustrated embodiment of system 800 includes a chassis 810, a monitor 815, a mouse 820 (or other pointing device), and a keyboard 825. The illustrated embodiment of chassis 810 further includes a floppy disk drive 830, a hard disk 835, a compact disc (“CD”) and/or digital video disc (“DVD”) drive 837, a power supply (not shown), and a motherboard 840 populated with appropriate integrated circuits including system memory 845, nonvolatile (“NV”) memory 850, and one or more processor(s) 500.

Processor(s) 500 is communicatively coupled to system memory 845, NV memory 850, hard disk 835, floppy disk drive 830, and CD/DVD drive 837 via a chipset on motherboard 840 to send and to receive instructions or data thereto/therefrom. In one embodiment, NV memory 850 is a flash memory device. In other embodiments, NV memory 850 includes any one of read only memory (“ROM”), programmable ROM, erasable programmable ROM, electrically erasable programmable ROM, or the like. In one embodiment, system memory 845 includes random access memory (“RAM”), such as dynamic RAM (“DRAM”), synchronous DRAM, (“SDRAM”), double data rate SDRAM (“DDR SDRAM”) static RAM (“SRAM”), and the like. Hard disk 835 represents any storage device for software data, applications, and/or operating systems, but will most typically be a nonvolatile storage device. Hard disk 835 may optionally include one or more of an integrated drive electronic (“IDE”) hard disk, an enhanced IDE (“EIDE”) hard disk, a redundant array of independent disks (“RAID”), a small computer system interface (“SCSI”) hard disk, and the like.

In one embodiment, a network interface card (“NIC”) (not shown) is coupled to an expansion slot (not shown) of motherboard 840. The NIC is for connecting system 800 to a network 860, such as a local area network, wide area network, or the Internet. In one embodiment network 860 is further coupled to a remote computer 865, such that system 800 and remote computer 865 can communicate. System 800 may transmit software logs 150 over network 560 to a central repository located on remote computer 865.

As described above, record-of-age circuits 100 may be incorporated into processor 500, as well as, various other integrated circuits. Descriptions of record-of-age circuits 100 may be generated and compiled for incorporation into processor 500 or other various application specific integrated circuits (“ASICs”). For example, behavioral level code describing record-of-age circuit 100, or portions thereof, may be generated using a hardware descriptive language, such as VHDL or Verilog, and stored to a machine-accessible medium (e.g., CD-ROM, hard disk, floppy disk, etc.). Furthermore, the behavioral level code can be compiled into register transfer level (“RTL”) code, a netlist, or even a circuit layout and stored to a machine-accessible medium. The behavioral level code, the RTL code, the netlist, and the circuit layout all represent various levels of abstraction to describe embodiments of record-of-age circuit 100.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A semiconductor die, comprising:
a circuit component coupled to receive a logic clock signal and to execute a function during operation;
a reference oscillator circuit to generate a reference clock signal having a reference frequency;
an aging oscillator circuit to generate an aging clock signal having an aging frequency that degrades during operation of the circuit component; and
a frequency comparator coupled to compare the aging frequency with the reference frequency to generate an age signal being dependent upon an operational age of the circuit component.

2. The semiconductor die of claim 1, wherein:
the aging oscillator circuit is disposed adjacent to the circuit component; and
the reference oscillator is electrically isolated from the circuit component during normal operation.

3. The semiconductor die of claim 2, further comprising:
a first enable unit coupled to enable the aging oscillator circuit during operation of the circuit component; and
a second enable unit coupled to disable the reference oscillator during the operation of the circuit component, except when the frequency comparator compares the aging frequency with the reference frequency.

4. The semiconductor die of claim 3, further comprising multiple aging oscillators disposed adjacent to the circuit component, each aging oscillator to track an amount of time the circuit component operates in one of multiple operating modes, each aging oscillators coupled to be enabled by the second enable unit during a corresponding one of the multiple operating modes.

5. The semiconductor die of claim 3, further comprising:
a clock regulator circuit coupled to regulate a clock frequency of the logic clock signal in response to the age signal.

6. The semiconductor die of claim 5, further comprising:
a clock control unit coupled to generate a control signal in response to the age signal, the control signal coupled to the clock regulator circuit to reduce the clock frequency of the logic clock, if the age signal indicates that the circuit component has exceeded a reliable lifetime for a given clock frequency.

7. The semiconductor die of claim 3, further comprising a test access port (“TAP”) coupled to output the age signal.

8. The semiconductor die of claim 3, further comprising a computational unit coupled to receive the aging signal, the computational unit coupled to generate an aging log of the circuit component.

9. The semiconductor die of claim 8, further comprising a memory device communicatively coupled to the computational unit to store the aging log.

10. The semiconductor die of claim 3, wherein the reference oscillator circuit and the aging oscillator circuit comprise ring oscillators.

11. The semiconductor die of claim 10, wherein the reference ring oscillator comprises:
an odd number of cascaded inverter circuits, a last one of the inverter circuits having an output coupled to an input of a first one of the inverter circuits to oscillate the reference clock signal around the cascaded inverter circuits; and
first enable transistors each coupled in series between one of the inverter circuits and a VSS power path to selectively cutoff the inverter circuits from the VSS power path;
a second enable transistor coupled to selectively short nodes between the inverter circuits and the first enable transistors to a VCC power path when the first enable transistors cutoff the inverter circuits from the VSS power path to disable the inverter circuits, the second enable transistor coupled to selectively short the nodes in response to the second enable unit.

12. The semiconductor die of claim 10, wherein the aging ring oscillator comprises:
an odd number of cascaded inverter circuits, a last one of the inverter circuits having an output coupled to an input of a first one of the inverter circuits to oscillate the aging clock signal around the cascaded inverter circuits; and
a first transistor coupled in series between one of the inverter circuits and a VSS power path to selectively cutoff the one of the inverter circuits from the VSS power path; and
a second transistor coupled to short a node between the one of the inverter circuits and the first transistor to a VCC power path when the first transistor cutoffs the one of the inverter circuits from the VSS power path to disable the aging ring oscillator, the first and second transistors responsive to the second enable unit.

13. The semiconductor die of claim 2, wherein the circuit component comprises one of an arithmetic logic unit (“ALU”) and a floating point math unit (“FPU”).

14. The semiconductor die of claim 2, further comprising:
multiple circuit components; and
multiple aging oscillator circuits each disposed adjacent to one of the multiple circuit components to track operational ages of each of the multiple circuit components.

15. A method, comprising:
enabling an aging oscillator circuit disposed in a semiconductor die during operation of a circuit component disposed within the semiconductor die;
generating an aging clock signal having an aging frequency that degrades during operation of the circuit component; and
comparing the aging frequency with a reference frequency of a reference clock signal to determine an approximate operational age of the circuit component.

16. The method of claim 15, wherein comparing the aging frequency with the reference frequency comprises:
enabling a reference oscillator circuit;
generating the reference clock signal having the reference frequency;
comparing the aging frequency with the reference frequency to determine a difference between the aging frequency and the reference frequency to determine the approximate operational age of the circuit component; and
disabling the reference oscillator circuit after the comparing to prevent the reference frequency from degrading overtime.

17. The method of claim 16, further comprising:
logging data indicative of the operational age of the circuit component; and
reporting the logged data to a remote computer via a network to track operational use of the circuit component.

18. The method of claim 15, further comprising:
operating the circuit component within one of multiple operating modes; and
enabling one of multiple aging oscillator circuits disposed in the semiconductor die adjacent to the circuit component, each of the multiple aging oscillator circuits corresponding to each of the multiple operating modes to track operation time of the circuit component spent in each of the operating modes.

19. The method of claim 18, wherein the operating modes comprise power states defined by an Advanced Configuration and Power Interface standard.

20. The method of claim 18, further comprising:
logging data indicative of the operation time of the circuit component spent in each of the operating modes; and
reporting the logged data to a remote computer via a network to track operational use of the circuit component.

21. The method of claim 15, further comprising:
determining whether the approximate operational age of the circuit component has exceeded a reliable lifetime of the circuit component at a given operating frequency; and
reducing the operating frequency, if the determining determines that the approximate operational age has exceeded the reliable lifetime.

22. The method of claim 21, further comprising reducing an operating voltage applied to the circuit component, if the determining determines that the approximate operation age has exceeded the reliable lifetime.

23. The method of claim 15, further comprising:
enabling each of multiple aging oscillator circuits during operation of corresponding circuit components, each multiple aging oscillator disposed within the semiconductor die adjacent to a corresponding one of the multiple circuit components;
generating multiple aging clock signals having multiple aging frequencies that each degrade during operation of the corresponding one of the circuit components; and
comparing the aging frequencies with reference frequencies of reference clock signals to determine approximate operation ages of the circuit components of the semiconductor die.

24. A machine-accessible medium having contained thereon a description of an integrated circuit, the integrated circuit comprising:
a circuit component coupled to receive a logic clock signal and to execute a function during operation;
a reference oscillator circuit to generate a reference clock signal having a reference frequency;
an aging oscillator circuit disposed proximate to the circuit component to experience a substantially equivalent temperature as the circuit component during operation of the circuit component, the aging oscillator coupled to generate an aging clock signal having an aging frequency that degrades during operation of the circuit component; and
a frequency comparator coupled to compare the aging frequency with the reference frequency to generate an age signal being dependent upon an operational age of the circuit component.

25. The machine-accessible medium of claim 24, wherein the integrated circuit further comprises:
a first enable unit coupled to enable the aging oscillator circuit during operation of the circuit component; and
a second enable unit coupled to disable the reference oscillator during the operation of the circuit component, except when the frequency comparator compares the aging frequency with the reference frequency.

26. The machine-accessible medium of claim 24, wherein the circuit component comprises a floating point match unit.

27. A system, comprising:
synchronous dynamic random access memory (“SDRAM”); and
a processor coupled to access the SDRAM, the processor including:
a circuit component coupled to receive a logic clock signal and to execute a function during operation;
a reference oscillator circuit to generate a reference clock signal having a reference frequency;
an aging oscillator circuit disposed adjacent to the circuit component to generate an aging clock signal having an aging frequency that degrades during operation of the circuit component; and
a frequency comparator coupled to compare the aging frequency with the reference frequency to generate an age signal being dependent upon an operational age of the circuit component.

28. The system of claim 27, wherein the processor further includes:
a first enable unit coupled to enable the aging oscillator circuit during operation of the circuit component; and
a second enable unit coupled to disable the reference oscillator during the operation of the circuit component, except when the frequency comparator compares the aging frequency with the reference frequency.

29. The system of claim 28, wherein the processor further includes a clock regulator circuit coupled to regulate a clock frequency of the logic clock signal in response to the age signal.

30. The system of claim 29, wherein the processor further includes a computational unit coupled to receive the aging signal, the computational unit coupled to generate an aging log of the circuit component.
